(19) United States
(12) Patent Application Publication
(10) Pub. No.: US 2010/0329471 A1
(43) Pub. Date: Dec. 30, 2010

(54) AMBIENT NOISE COMPENSATION SYSTEM

(75) Inventors: William Dunn, Alpharetta, GA (US); Hanwook Baek, Cummings, GA (US)

Correspondence Address: STANDLEY LAW GROUP LLP, 6300 Riverside Drive, Dublin, OH, 43017, US

(73) Assignee: Manufacturing Resources International, Inc., Alpharetta, GA (US)

(21) Appl. No.: 12/639,651

(22) Filed: Dec. 16, 2009

Related U.S. Application Data
(60) Provisional application No. 61/122,774, filed on Dec. 16, 2008.

(51) Int. Cl. H03G 3/20

(52) U.S. Cl. 381/57

(57) ABSTRACT

An ambient noise compensation system having an automatic gain control to adjust the volume of a desired sound in a listening area. A sound pick-up may be placed in the listening area to capture the sound level, including both the desired sound and ambient noise. A measured value is then determined based on the sound level received by the sound pick-up. The measured value may then be compared to a predictive value to determine an acceptable range. The gain control automatically adjusts the volume of the desired sound to maintain the measured sound within the acceptable range.

### CROSS-REFERENCE TO RELATED APPLICATIONS

This application claims priority to U.S. Application No. 61/122,774, filed Dec. 16, 2008, which is incorporated hereby by reference as if fully rewritten herein.

### TECHNICAL FIELD

The present invention relates generally to sound processing systems. More particularly, the invention related to sound processing systems that automatically adjust the sound output based on the ambient noise level in an outdoor listening area.

### BACKGROUND AND SUMMARY OF THE INVENTION

In any listening area, compensation must be made to deal with ambient noise. Sound systems must be able to play the desired sound at a level sufficient to overcome the ambient noise. The desired sound produced from the sound system must be able to be heard over the ambient noise in the listening area. To accomplish this, measurements of the ambient noise in the listening area are taken and the volume of the desired sound adjusted accordingly. However, this task becomes increasingly difficult when the ambient noise increases and decreases over time.

Outdoor listening areas frequently encounter increasing and decreasing ambient noise. Many variables contribute to the ambient noise in an outdoor listening area, such as the addition of people to the listening area, passing motor vehicle traffic, low flying aircraft, or any number of sound producing affects. In addition, outdoor listening areas have the possibility of rain and wind contributing to the ambient noise of the listening area.

To allow the desired sound to be audible over the varying ambient noise in a listening area, measurements of the ambient noise must be made in real-time. The volume of the desired sound produced by the sound system must be increased as the ambient noise increases in the listening area, so as to maintain a pleasant listening area. Likewise, the volume of the desired sound produced by the sound system must be decreased as the ambient noise decreases in the listening area. This approach ensures that the desired sound remains audible during periods of high ambient noise, while having the ability to lower the volume of the desired sound to a comfortable level in the listening area during times of low ambient noise.

A problem that has plagued ambient noise compensation systems has been the system's ability to determine the sound contribution from the desired sound and the ambient noise to the sound level in the listening area. To help determine the sound level a microphone may be placed in the listening area. As the microphone receives the sound level from the listening area, it is receiving both the desired sound and the ambient noise. Since the microphone is receiving both the desired sound and the ambient noise, the attached sound system must have a means of differentiating between the desired sound and ambient noise. It is precisely this differentiation that some existing sound systems fail to account for when analyzing the sound level of the listening area received by the microphone and in turn begin a cycle where the volume of the desired sound is continuously increased making the volume uncomfortable in the listening area.

Various techniques have been employed to analyze the sound level received from the microphone and to differentiate the desired sound from the ambient noise. Although analyzing the sound level from the listening area, these techniques still have problems. Some techniques have potential error rates greater than the difference between the desired sound and the ambient noise. Other utilized techniques have problems with delay in the calculations or are complex in their design. Still other techniques are limited to certain applications where the ambient noise must be monitored in ways other than through the use of microphones.

In addition, current ambient noise compensation systems fail to account for multiple listening areas. These failures are only compounded in attempting to adjust desired sound levels in multiple listening areas where the listening areas may overlap one another. This overlap in listening areas may lead to a cycle where the volume of the desired sound in a first listening area may be increased to overcome the desired sound being produced in a second listening area and vice-versa. This cycle may lead to an uncomfortable volume increase across all listening areas.

To eliminate the problems associated with other noise compensation systems, the claimed invention determines a reference value. To determine the reference value a digital audio signal may be run through a low pass filter and down sampled. The resultant signal consisting of the frequency components in the audible range is then subjected to a numerical process having a time window. The numerical process produces the reference value. Next, the ambient noise compensation system needs to determine the actual measured sound levels in the listening area. To accomplish this, a sound pick-up is placed in the listening area. The information received by the sound pick-up is digitalized and subjected to a numerical process having a time window producing a measured value. The measure value is the combination of the desired sound and ambient noise present in the listening area allowing the system to distinguish between the desired sound and the ambient noise by comparing the reference and measured values.

To accurately compensate for the ambient noise the system employs a predictive value. The predictive value is obtained by applying a transformation function to the reference value. To ensure the most accurate predictive value, the transformation function should be analyzed in a low noise or noiseless environment. After the predictive value is obtained it is then compared to the measured value to derive the difference. It is this difference that used to determine whether the volume of the desired sound needs to be increased or decreased to maintain the desired sound at an audible and comfortable level. If a change in volume is required the ambient noise compensation system may adjust the gain of the sound system output automatically.

In addition to the novel features and advantages mentioned above, other objects and advantages of the present invention will be readily apparent from the following descriptions of the drawings and exemplary embodiments.

### BRIEF DESCRIPTION OF THE DRAWINGS

A better understanding of the disclosed embodiments will be obtained from a reading of the following detailed description and the accompanying drawings wherein identical reference characters refer to identical parts in which:

FIG. 1 is a block diagram illustrating how a reference value may be obtained.

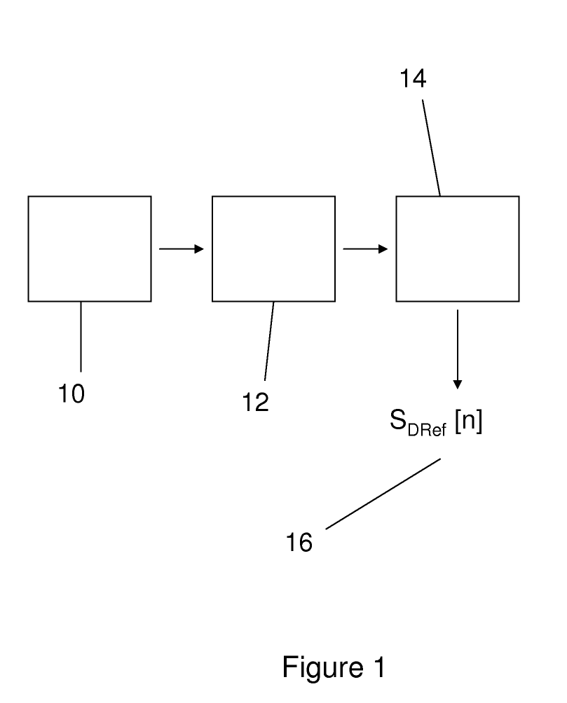

FIG. 2 is a diagram illustrating how a measured value may be obtained.

FIG. 3 is a diagram illustrating how a guessed value may be obtained.

FIG. 4 is a display housing that may be used with an exemplary embodiment of the ambient noise compensation system.

### DETAILED DESCRIPTION OF EXEMPLARY EMBODIMENT(S)

Exemplary embodiments are directed to an ambient noise compensation system and a method of ambient noise compensation. Exemplary embodiments may be used for outdoor and indoor listening areas and outdoor and indoor venues having multiple listening areas.

A sound system that may be used with exemplary embodiments may be a digital audio system. It should be recognized by one skilled in the art that an analog system may also be used. To obtain a reference value 16 a digital audio system may be played at a high resolution and may have highly sampled data in the digital side of the system. This high-frequency sampled audio data 10 may be down sampled and pass through a low pass filter 12. The down sampling and passage through a low pass filter may ensure that only frequency components in the audible frequency are transmitted. The signal is then subjected to a numerical process with a time window 14. The resultant value is the reference value (S_{DRef}[n]) 16 and may stand for the amount of sound for that time window and be used for ambient noise compensation.

After the reference value 16 has been obtained a measured value 30 needs to be determined. To find the measured value 30 the digital data may be sent to a digital to analog converter 20. The digital to analog converter 20 may also have a gain control 32. After the signal has been converted to analog, the signal is transmitted to at least one speaker 22. The speaker 22 then converts the analog signal to audible sound.

A sound pick-up 24 is positioned in the listening area of speaker 22. The sound pick-up 24 may be any device capable of receiving sound waves including, but not limited to, microphones, piezoelectric microphones, contact microphones, and any other suitable device. As the sound pick-up 24 is positioned in the listening area, so as to receive the sound produced by the speaker 22, ambient noise in the listening area is also received by the sound pick-up 24.

The sound pick-up 24 may then transmit a signal from the listening area; both desired sound and ambient noise, to an analog to digital converter 26. The signal may also be passed through a low pass filter. After the signal has been converted to a digital, it may then be run through a numerical process having a time window 28. The resultant value is the measured value 30.

As the measured value 30 is derived from the audio levels of the listening area as received by sound pick-up, the measured value 30 may be different than the reference value 16. It is this mutuality between the reference value 16 and the measured value 30 that is important ambient noise compensation. The complexity of this analysis may be affected mostly be the analog portion of the system, specifically, the characteristics of the sound pick-up and its physical environment for sensing.

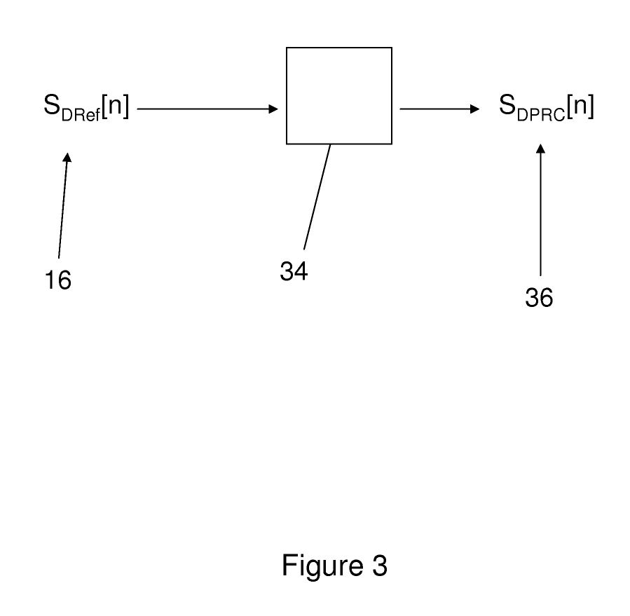

As the measured value 30 is not equal to the reference value 16, a transformation function 34 may be needed, as shown in FIG. 3. The transformation function 34 may be used to determine a predictive value 36. In order to accurately arrive at the predictive value 36 the transformative function 34 may be analyzed in a noiseless environment. After the predictive value 36 is ascertained, it may be compared to the measured value 30. It is this comparison that allows for auto-adjusting the volume so as to compensate for ambient noise and fluctuations therein.

If the predictive value 36 is A, and the measured value 30 is B then:

A−B=C

where C is the value difference between the predictive value 36 and the measured value 30. It is this calculation of C that allows auto-adjusting of the desired sound to compensate for ambient noise. Although C may have a definite value, in actual implementation, C may be given an acceptable range. By using a range of values for C, the ambient noise compensation may be able to compensate for variations between sound systems and audio sound data's randomness. Further the use of a range may allow the absorption of other potential environment error factors. To state it another way the acceptable range may be defined by:

Under this model if C is positive and above D, the ambient noise may be presumed to be sufficient to interfere with the desired sound in the listening area. If the ambient noise is determined to be interfering then the volume level of the desired sound may be increased until C is within the acceptable range, D. If the volume of the desired sound needs to be adjusted to be within the acceptable range a signal may be sent to the gain control 32. The gain control 32 may then automatically adjust the volume of the desired sound.

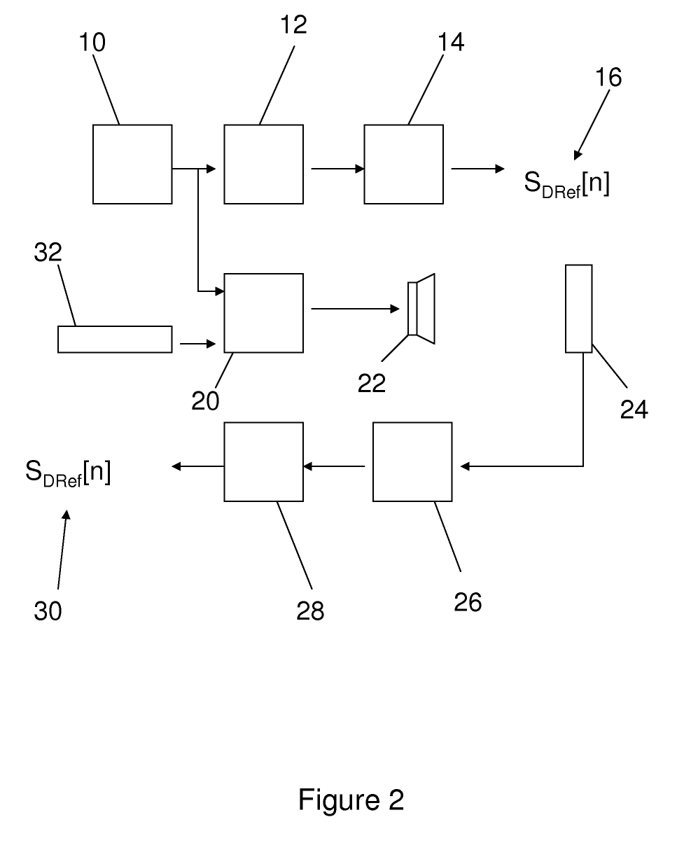

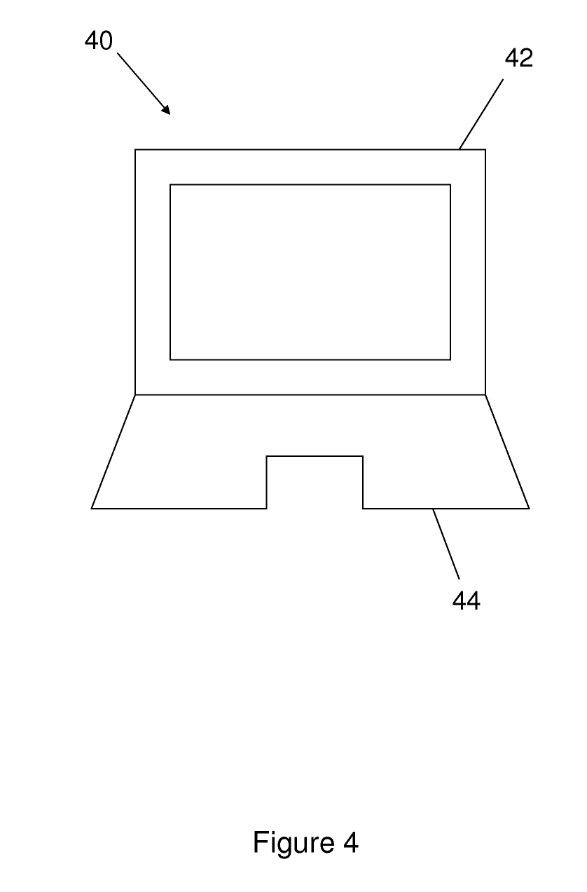

FIG. 4 illustrates a display 40 having a housing 42 and a stand 44 that may employ exemplary embodiments of the ambient noise compensation system. Although provided as an example, it should be understood by those skilled in the art that other displays and sound systems may benefit from the ambient noise compensation system such as those described in U.S. application Ser. No. 12/248,255 filed Oct. 9, 2008, which is hereby incorporated by reference in its entirety. To take advantage of the ambient noise compensation system the components as shown in FIG. 2 may be located within the housing 42. The sound pick-up 24 may be a contact microphone fixed to the housing 42. To facilitate efficient sound transfer the housing 42 may be constructed of metal or other suitable material. In other embodiments, multiple displays 40 may be arranged to provide multiple listening areas wherein listening areas may overlap. The use of the ambient noise compensation system may allow for audible yet comfortable volume across all listening areas.

Any exemplary embodiment may include any of the optional or preferred features of the other embodiments. The exemplary embodiments herein disclosed are not intended to be exhaustive or to unnecessarily limit the scope of the invention. The exemplary embodiments were chosen and described in order to explain the principles of the claimed invention so that others skilled in the art will realize that many variations and modifications may be made to affect the described invention. Many of those variations and modifications will provide the same result and fall within the spirit of the claimed invention. It is the intention, therefore, to limit the invention only as indicated by the scope of the claims.

What is claimed is:

1. An ambient noise compensation system, comprising:
an audio source having a reference value, said reference value passed through a transformation function to obtain a predictive value;
a speaker system in communication with said audio source, the speaker system providing a desired sound to a listening area;
a sound pick-up positioned in said listening area, the sound pick-up receiving the desired sound and ambient noise present in the listening area used to determine a measured value;
an analyzer, said analyzer comparing the measured value and the predictive value to determine an acceptable range;
a gain control in association with said speaker system, said gain control automatically adjusting the volume of the desired sound so as to maintain said measured value within said acceptable range.

2. The ambient noise compensation system of claim 1 wherein said sound pick-up is a contact microphone.

3. The ambient noise compensation system of claim 1 wherein said sound pick-up is a piezoelectric microphone.

4. The ambient noise compensation system of claim 3 wherein said piezoelectric microphone is attached to a housing containing said ambient noise compensation system.

5. The ambient noise compensation system of claim 1 wherein the predictive value is determined in a substantially noiseless environment.

6. The ambient noise compensation system of claim 1 wherein said audio source is a digital audio source.

7. The ambient noise compensation system of claim 6 wherein the digital audio source passed through a low-pass filter and downsampler.

8. The ambient noise compensation system of claim 1 wherein the desired sound and ambient noise received by the sound pick-up is passed through a low-pass filter and digitized.

9. An method of ambient noise compensation, comprising:
providing a digital audio source producing audio data;
determining a reference value;
driving a sound system using said audio data, to produce a desired sound;
measuring said desired sound and ambient noise in a listening area, to determine a measured value;
transforming said reference value using a transformation function to obtain a predictive value;
comparing said measured value and said predictive value to determine an acceptable range;
comparing said measured value to said acceptable range; and
adjusting the volume of said sound system automatically to maintain the measured value within said acceptable range.

10. The method of ambient noise compensation of claim 9, wherein the reference value is determined after the audio data has passed through a low-pass filter and downsampled.

11. The method of ambient noise compensation of claim 9 wherein the said desired sound and ambient noise in said listening area is measured with a sound pick-up.

12. The method of ambient noise compensation of claim 11 wherein said sound pick-up is a piezoelectric microphone.

13. The method of ambient noise compensation of claim 9, applying a numerical process having a time window to said audio data.

14. The method of ambient noise compensation of claim 9 wherein the predictive value is determined in a substantially noiseless environment.

15. The method of ambient noise compensation of claim 9 wherein the sound system volume is adjusted automatically by a gain control.

16. The method of ambient noise compensation of claim 11 wherein a low-pass filter and digitizer are applied to the desired sound and ambient noise received by the sound pick-up.

17. The method of ambient noise compensation of claim 11 wherein a numerical process having a time window are applied to the desired sound and ambient noise received by the sound pick-up.

18. An method of ambient noise compensation, comprising:
providing a digital audio source producing audio data;
passing said audio data through a low-pass filter and a downsampler;
applying a numerical process having a time window to said audio data to determine a reference value;
driving a sound system using said audio data, to produce a desired sound;
measuring said desired sound and ambient noise in a listening area using a piezoelectric microphone;
transforming said reference value using a transformation function to obtain a predictive value;
filtering said desired sound and the ambient noise received by said piezoelectric microphone using a low-pass filter and a digitizer;
applying a numerical process having a time window to said desired sound and the ambient noise received by said piezoelectric microphone to produce a measured value;
comparing said measured value and said predictive value to determine an acceptable range;
comparing said measured value to said acceptable range; and
adjusting the volume of said sound system automatically to maintain the measured value within said acceptable range.

19. The method of ambient noise compensation of claim 18 wherein said predictive value is determined a substantially noiseless environment.

20. The method of ambient noise compensation of claim 18 wherein said piezoelectric microphone is fixed to a housing.
